(19) United States
(12) Patent Application Publication
(10) Pub. No.: US 2025/0027199 A1
(43) Pub. Date: Jan. 23, 2025

(54) SEMICONDUCTOR CHEMICAL PRECURSOR WITH GAS PASSAGES

(71) Applicant: Applied Materials, Inc., Santa Clara, CA (US)

(72) Inventor: David Marquardt, Scottsdale, AZ (US)

(73) Assignee: Applied Materials, Inc., Santa Clara, CA (US)

(21) Appl. No.: 18/222,671

(22) Filed: Jul. 17, 2023

(51) Int. Cl. C23C 16/455; C23C 16/448; H01L 21/02

(52) U.S. Cl. CPC C23C 16/45561; C23C 16/4483; H01L 21/0262

(57) ABSTRACT

Ampoules including a solid volume of the semiconductor chemical precursor and methods of use and manufacturing are described. The solid volume of the semiconductor chemical precursor includes an ingress opening, at least one flow channel, and an outlet passage that are in fluid communication with each other. The solid volume of the semiconductor manufacturing precursor is made of a porous or alternatively a non-porous material. A flow path is defined by at least one flow channel through which a carrier gas flows in contact with the solid volume of the semiconductor chemical precursor.

### TECHNICAL FIELD

The present disclosure relates generally to ampoules for and methods of delivering semiconductor chemical precursors to semiconductor processing chambers. In particular embodiments, the disclosure relates to ampoules with solid semiconductor chemical precursors and methods to provide a tortuous flow path for semiconductor chemical precursor. In more particular embodiments, the disclosure relates to solid semiconductor chemical precursors with a tortuous flow path and methods of making the same.

### BACKGROUND

The semiconductor industry is using an increasing variety of liquid and solid precursors, also referred to as “chemistries,” for chemical vapor deposition (CVD) and atomic layer deposition (ALD) processes. The precursor or chemistry is typically inside a closed vessel or an ampoule with a single inlet and a single outlet, and the precursor is typically delivered to a semiconductor process chamber as a vapor using a carrier gas.

Solid precursors with a low vapor pressure typically utilize the carrier gas to carry the precursor vapor out of the ampoule to the semiconductor process chamber in vapor deposition processes. This type of process typically uses a cross-flow ampoule where the carrier gas sweeps a headspace in the ampoule above a quantity of solid precursor typically in particulate or granular form. Due to continuous sublimation of the solid semiconductor chemical precursor, the volume of the headspace of an ampoule varies and becomes larger during the delivery process. The change in the volume of the headspace adversely results in an inconsistent saturation of carrier gas and a lower lifetime of the precursor. Often, there is only a very short flow path for the carrier gas. The short flow path from the inlet to the outlet of the vessel does not allow adequate residence time within the vessel to allow the carrier gas to become fully saturated with vaporized or sublimed precursor. Other ampoules utilize “trays” or inserts to promote interaction of the carrier gas with more chemical surface area, thereby increasing saturation. Some existing ampoule designs do not evenly distribute the carrier gas across the entire surface of the precursor. Many other solid source ampoules do not provide a means for keeping precursor dust from traveling downstream where it hampers control valve performance or creates on-wafer particle issues.

There is a need in the art for ampoules that implement solid semiconductor chemical precursors having an adequate flow path to saturate or nearly saturate the carrier gas with the semiconductor chemical precursor, maintains consistent delivery of the precursor, and reduces generation of precursor dust.

### SUMMARY

A first aspect of the disclosure ampoule comprising a container defining a cavity configured to hold a solid volume of the semiconductor chemical precursor; an inlet port and an outlet port, both in fluid communication with the solid volume of the semiconductor chemical precursor; the solid volume of the semiconductor chemical precursor defined by a top edge, a bottom edge, a perimeter and at least one flow channel in the solid volume of the semiconductor chemical precursor; and at least one flow path defined by the at least one flow channel through which a carrier gas flows in contact with the solid volume of the semiconductor chemical precursor.

A second aspect of the disclosure pertains to a method forming a film in a semiconductor processing chamber, the method comprising flowing a carrier gas through an inlet port of an ampoule having a solid volume of a semiconductor chemical precursor therein; directing the flow of the carrier gas within the ampoule and in contact with the solid volume of a semiconductor chemical precursor through at least one flow path defined by at least one flow channel in the solid volume of a semiconductor chemical precursor, the at least one flow channel having an ingress opening, through which a carrier gas flows in contact with the solid volume of a semiconductor chemical precursor and an outlet passage through which the carrier gas flows out of the solid volume of a semiconductor chemical precursor; and flowing the carrier gas and the semiconductor chemical precursor out of the ampoule through the outlet passage to an outlet port.

A third aspect of the disclosure pertains to a solid volume of a semiconductor chemical precursor, comprising a top edge, a bottom edge, and a perimeter defining a solid volume of the semiconductor chemical precursor, the semiconductor chemical precursor having at least one flow channel, an ingress opening, and an outlet passage, wherein the at least one flow channel is in fluid communication with the ingress opening and the outlet passage; and at least one flow path defined by the at least one flow channel through which a carrier gas flows in contact with the semiconductor chemical precursor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is an isometric view of an ampoule and an accompanying manifold having an “outer-to-inner flow” configuration in accordance with an embodiment;

FIG. 1B is an isometric view of an ampoule and an accompanying manifold having an “inner-to-outer flow” configuration in accordance with another embodiment;

FIG. 2 is an isometric view of a semiconductor chemical precursor solid volume according to an embodiment;

FIG. 3 is a cross-sectional view of an ampoule containing a semiconductor chemical precursor solid volume according to an embodiment;

FIG. 4 is bottom view of an ampoule containing a semiconductor chemical precursor solid volume according to an embodiment;

FIG. 5A is an isometric view of a core portion of a mold to form a semiconductor chemical precursor solid volume; and

FIG. 5B is an isometric view of an assembled mold to form a semiconductor chemical precursor solid volume.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label. The cross-hatched shading of the components in the figures are intended to aid in visualization of different parts and do not necessarily indicate different materials of construction.

### DETAILED DESCRIPTION

Before describing several exemplary embodiments of the disclosure, it is to be understood that the disclosure is not limited to the details of construction or process steps set forth in the following description. The claimed ampoules and methods are capable of other embodiments and of being practiced or being carried out in various ways.

Some embodiments of the disclosure advantageously provide a long flow path for a carrier gas from ampoule inlet to outlet for the delivery of low vapor pressure precursors, e.g., solid source precursor. Low vapor pressure precursors are understood to refer to materials that do not readily vaporize under atmospheric conditions. Low vapor pressure precursors typically have a vapor pressure of less than 10 Torr, and more typically less than 1 Torr. In some applications, a carrier gas is used to deliver low vapor pressure material from an ampoule to a reactor. Low vapor pressure materials typically require heat to increase the vapor pressure. A non-limiting list of exemplary precursors includes ZrCl₄, Y(EtCP)₃, HfCl₄, WCl₅, MoCl₅, and In(CH₃)₃.

A long flow path within a solid volume of the semiconductor chemical precursor containing a precursor allows the carrier gas adequate residence time to become partially to nearly to fully saturated with vaporized and/or sublimed and/or entrained precursor that is carried by a carrier gas flowing through the ampoule. Reference herein to “saturated” allows for varying degrees of saturation.

Some embodiments advantageously control uneven depletion of the precursor. Some embodiments advantageously provide even distribution of the carrier gas along the at least one channel. Embodiments herein provide improved doses of the semiconductor chemical precursor to substrate processing chambers, for example, atomic layer deposition chambers and chemical vapor deposition chambers that are used to deposit layers formed from semiconductor chemical precursors onto substrates, such as semiconductor substrates and other substrates used in microelectronic manufacturing. Designs provided herein may offer a high capacity (volume) ampoule in a smaller footprint than other designs. Designs herein are easy to clean and be refilled. Designs herein can contain precursor charges (i.e., amounts of precursor) of up to 10-20 kilograms.

In some embodiments, the ampoules contain at least one channel defining a labyrinth such that the flow path is tortuous. Advantageously, one or more embodiments provide a flow path whose distance can be five to ten times longer than distances found with common ampoules. Generally, according to one or more embodiments, an ampoule comprises a container defining a cavity configured to hold and contain a solid volume of the semiconductor chemical precursor; an inlet port and an outlet port, both in fluid communication with the solid volume of the semiconductor chemical precursor; the semiconductor chemical precursor forms a solid volume which is defined by a top edge, a bottom edge, a perimeter and at least one flow channel in the solid volume, and at least one flow path defined by the at least one flow channel through which a carrier gas flows in contact with the solid volume of the semiconductor chemical precursor.

In one or more embodiments, the flow path travels from an outermost channel to an innermost channel, which may be referred to as an “outer-to-inner flow” configuration. In one or more embodiments, the flow path travels from an innermost channel to an outermost channel, which may be referred to as an “inner-to-outer flow” configuration.

Generally, the flow paths provided herein force the carrier gas to flow around a series of channels defined in the solid volume of the semiconductor chemical precursor. It is understood that a series of channels will result in a desired flow path. In one or more embodiments, the channels are in the form of concentric arcs. As the gas flow along the channels, it contacts with the walls of channels and entrains the semiconductor chemical precursor by sublimation. The entrained semiconductor chemical precursor travels along the channels and out the outlet port.

In one or more particular embodiments, the carrier gas flows through a first fluid connection from the inlet import to the ingress opening in the at least one channels. The inlet is in fluid communication with the at least one channels and directs the gas in the at least one channels. As the carrier gas saturated with the semiconductor chemical precursor travels along the flow path and in the at least one channel, it reaches the outlet passage which is in fluid communication with the at least one channels, The outlet passage, itself, is in fluid communication with a second fluid connection that directs the saturated carrier gas to the outlet port.

In one or more particular embodiments, the solid volume of the semiconductor chemical precursor is manufactured with molding techniques. In one particular embodiment, a mixture containing the semiconductor chemical precursor is injected into a negative mold. In some embodiments, the mixture is molten and shapes upon cooling. In other embodiments, the mixture comprises binders wherein the solid volume forms upon curing of the binder. In some embodiments, the binder is a thermoset or thermoplastic material. In some embodiments the mixture is a powder that comprises the semiconductor chemical material, the powder is injected in a mold and then compressed to form the solid volume. In some embodiments the powder is heated while being compressed. It is understood that the mold is designed to reflect the desired features of the solid volume, for example, the channels, the ingress opening, the outlet passage, etc.

In one or more particular embodiments, the solid volume of the semiconductor chemical precursor is manufactured with casting techniques. A slurry of the semiconductor chemical precursor is poured in a negative mold to form the solid volume of the semiconductor chemical precursor. Gravity, gas pressure and vacuum can be used to fill the negative mold.

In one particular embodiment, the solid volume of the semiconductor chemical precursor is manufactured with machining techniques. A block of the semiconductor chemical precursor is manufactured by casting or molding techniques. The block is then CNC-machined to form the solid volume. In some embodiments, the molding comprises molding a powder precursor to form the solid volume of the semiconductor chemical precursor.

In one or more particular embodiments, the solid volume of the semiconductor chemical precursor is manufactured with 3D printing techniques. In some embodiments, direct metal laser sintering (DMLS) is used to manufacture the solid volume of the semiconductor chemical precursor. A laser is used to sinter a powder of the semiconductor chemical precursor to form the solid volume of the semiconductor chemical precursor layer by layer. In some embodiments, electron beam melting is used to manufacture the solid volume of the semiconductor chemical precursor. An electron beam is used to sinter a powder of semiconductor chemical precursor to form the solid volume of the semiconductor chemical precursor layer by layer.

In some embodiments, the solid volume of semiconductor chemical precursor comprises a non-porous material. In some embodiments, the solid volume of semiconductor chemical precursor comprises a porous material.

In some embodiments, the porosity of the porous material is in a range of 5-95 percent by volume. In some embodiments, the porosity of the porous material is in a range of 5-95, 5-90, 5-80, 5-70, 5-60, 5-50, 5-40, 5-30, 5-20 or 5-10 percent by volume. In some embodiments, the porosity of the porous material is in a range of 10-95, 10-90, 10-80, 10-70, 10-60, 10-50, 10-40, 10-30 or 10-20 percent by volume. In some embodiments, the porosity of the porous material is in a range of 20-95, 10-90, 20-80, 20-70, 20-60, 20-50, 20-40 or 20-30 percent by volume. In some embodiments, the porosity of the porous material is in a range of 30-95, 30-90, 30-80, 30-70, 30-60, 30-50 or 30-40 percent by volume. In some embodiments, the porosity of the porous material is in a range of 40-95, 40-90, 40-80, 40-70, 40-60, or 40-50 percent by volume. In some embodiments, the porosity of the porous material is in a range of 50-95, 50-90, 50-80, 50-70 or 50-60 percent by volume. In some embodiments, the porosity of the porous material is in a range of from 60-95, 60-90, 60-80, or 60-70 percent by volume.

In one or more embodiments, the at least one flow channel comprises a plurality of tortuous passages configured so that flow of the carrier gas through the ingress opening diverts the carrier gas into a first section in a first direction and a second section in a second direction and out the outlet passage.

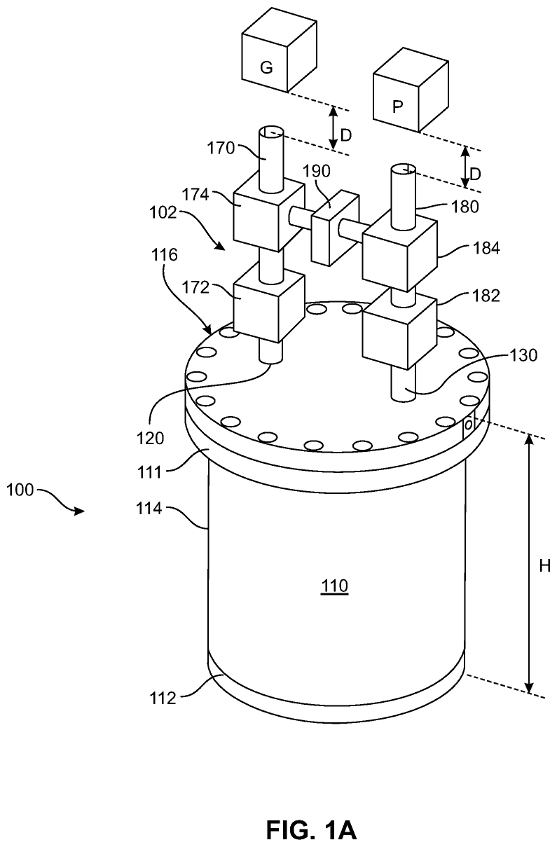

FIG. 1A and FIG. 1B respectively show isomeric views of an ampoule 100 and a manifold 102 having an “outer-to-inner flow” and “inner-to-outer flow” configurations in accordance with an embodiment. An ampoule 100 is suitable for use with semiconductor manufacturing raw materials, which include the solid volume of a semiconductor chemical precursor. The term “semiconductor chemical precursor” is used to describe the contents of the ampoule 100 and refers to any reagent that flows into a process environment such as a semiconductor processing chamber in which the precursor is delivered to a substrate surface in the process environment to form a film on the substrate.

The ampoule 100 includes a container 110 with a bottom wall 112, sidewalls 114, and a lid assembly 116 including a lid 111. An inlet port 120 and outlet port 130 are in fluid communication with a cavity defined by internal walls of the container 110. The inlet port 120 is generally configured to allow a connection to a gas source “G” by way of suitable piping and valve(s) and may have suitable threaded or sealing connections. In one or more embodiments, the gas source “G” is a carrier gas; in one or more embodiments, the carrier gas is inert. The outlet port 130 is also in fluid communication with the solid volume of the semiconductor chemical precursor. The outlet port 130 is generally configured to be able to connect to a line, including suitable piping and valve(s), to allow the flow of gases, which may include entrained particles, exiting the container 110 to flow to a processing chamber (or other component) “P”. The outlet port 130 may have a welded or threaded connection to allow a gas line to be connected. A height (H) of the cavity defined by the container 110 spans from a lower surface of the lid assembly 116 to a top surface (not shown) of the bottom wall 112.

Turning to FIG. 1B, which shows an inner-to-outer configuration. An ampoule 200 and a manifold 202 are suitable for use with semiconductor manufacturing raw materials, which include reagents and precursors. The ampoule 200 includes a container 210 with a bottom wall 212, sidewalls 214, and a lid assembly 216. An inlet port 220 and outlet port 230 are in fluid communication with the solid volume of the semiconductor chemical precursor 150. The inlet port 220 is generally configured to allow a connection to a gas source “G” by way of suitable piping and valve(s) and may have suitable threaded or sealing connections. In one or more embodiments, the gas source “G” is a carrier gas; in one or more embodiments, the carrier gas is inert. The outlet port 230 is also in fluid communication with the solid volume of the semiconductor chemical precursor 150. The outlet port 230 is generally configured to be able to connect to a line, including suitable piping and valve(s), to allow the flow of gases, which may include entrained particles, exiting the container 210 to flow to a processing chamber (or other component) “P”. The outlet port 230 may have a welded or threaded connection to allow a gas line to be connected. A height (H) of the cavity defined by the container 210 spans from a lower surface (not shown) of the lid assembly 216 to a top surface (not shown) of the bottom wall 212.

It will be appreciated that the flow of gas and precursor entrained in carrier gas through the embodiment shown in FIG. 1B is essentially reversed when compared to the embodiment shown and discussed with respect to FIG. 1A.

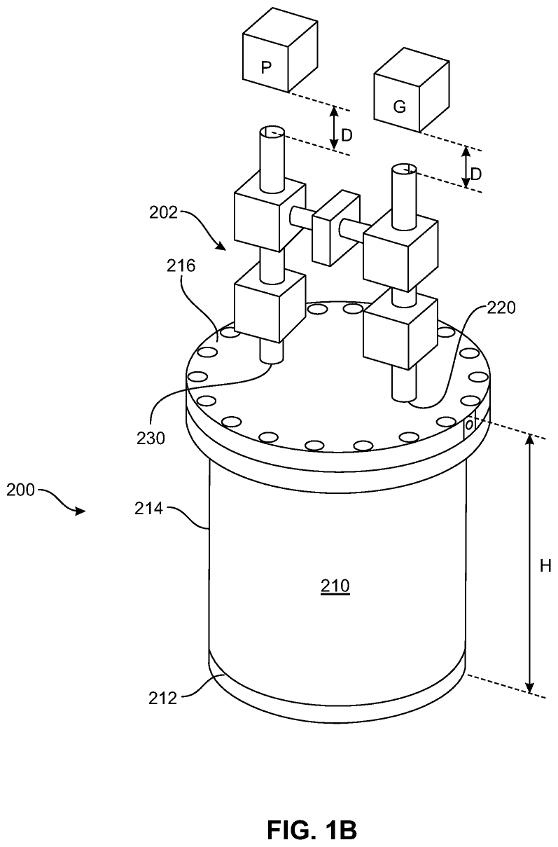

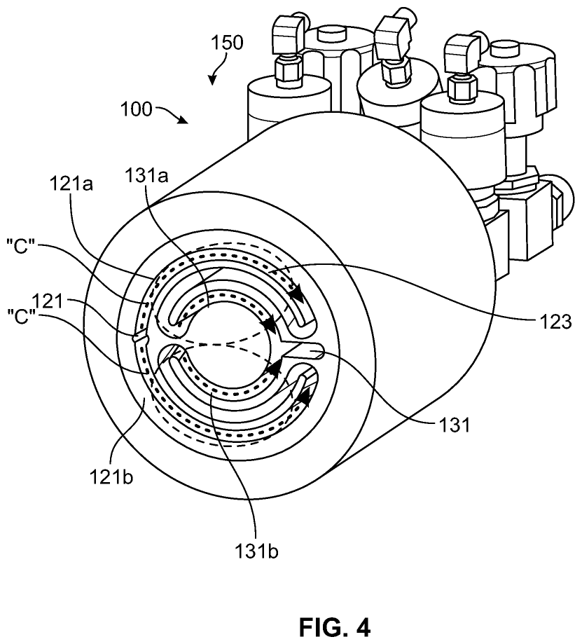

FIG. 2 shows a bottom perspective view of the solid volume of the semiconductor chemical precursor 150, and FIG. 4 shows the solid volume of the semiconductor chemical precursor 150 in the ampoule 100. The solid volume of the semiconductor chemical precursor 150 comprises at least one flow channel 123. The at least one flow channel 123 comprises an ingress opening 121, a first outer portion 121a and a first inner portion 131a in a first section 123a of the at least one flow channel 123 and a second outer portion 121b and a second inner portion 131b in a second section 123b of the at least one flow channel 123, which are in fluid communication with each other. The first outer portion 121a, the first inner portion 131a, the second outer portion 121b and the second inner portion 131b are arc-shaped. In some embodiments, the first outer portion 121a, the first inner portion 131a, the second outer portion 121b and the second inner portion 131b form concentric arcs that are in fluid communication with each other.

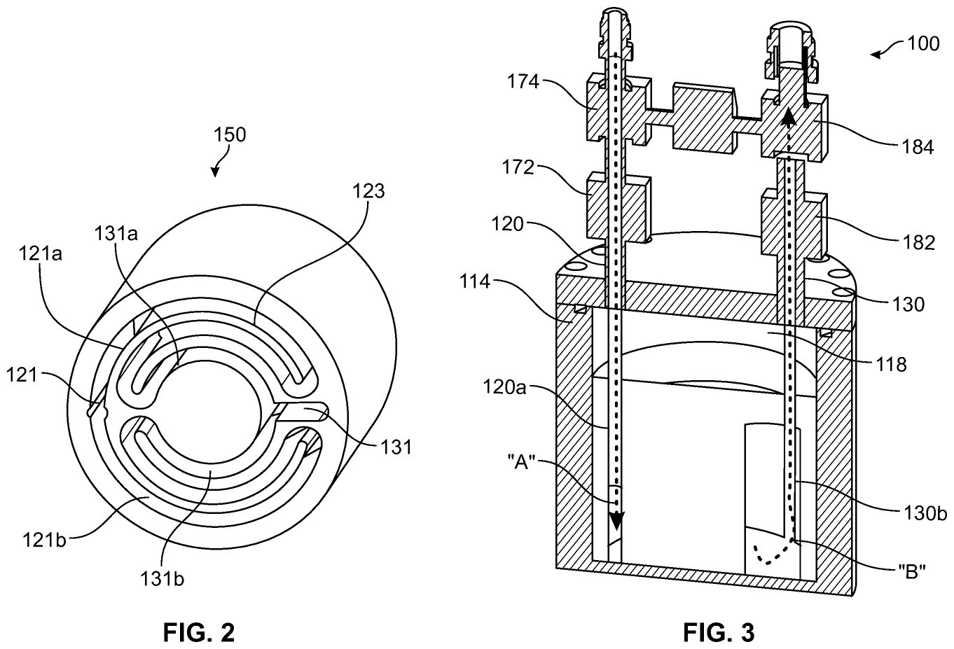

Turning to FIG. 3, and still in reference to FIG. 1A, FIG. 1B, and FIG. 2, shows a cross-section view of the ampoule, which comprises a single inlet port 120 and a single outlet port 130. While the embodiment of FIG. 3 depicts one of each an inlet and an outlet port, should a particular application require, multiple inlet ports and outlet ports may be present. Positioning of the inlet and outlet ports may be switched to accommodate other designs.

The inlet port 120 is in fluid communication with a first fluid connection 120a. The first fluid connection 120a is designed to accommodate a volume of incoming carrier gas from the inlet port 120, which in turn flows into the solid volume of the semiconductor chemical precursor 150.

The outlet port 130 is in fluid communication with a second fluid connection 130b, and the second fluid connection 130b is designed to accommodate a volume of outgoing carrier gas from the solid volume of the semiconductor chemical precursor, which in turn flows to the outlet port 130.

With specific regard to this embodiment, the cavity 118 contains the solid volume of the semiconductor chemical precursor. The solid volume of the semiconductor chemical precursor comprises at least one flow channel 123. The at least one flow channel 123 comprises an ingress opening 121 and an outlet passage 131. An ingress opening 121 is in fluid communication with a first fluid connection 120a that extends from the inlet port 120 to the ingress opening 121. The outlet passage 131 is in fluid communication with the outlet port 130 through a second fluid connection 130b that extends from the outlet passage 131 to the outlet port 130.

In some embodiments, the ampoule 100 includes the solid volume of the semiconductor chemical precursor 150, which in some embodiments is a low vapor pressure material within the cavity 118. The space above the solid volume of the semiconductor chemical precursor within the cavity 118 and below the lower of the lid assembly is referred to as the headspace of the ampoule 100. The solid volume of the semiconductor chemical precursor 150 can be a precursor for use with a semiconductor manufacturing process.

In some embodiments, as shown in FIG. 1.A and FIG. 1.B, the lid assembly 116 is a separate component from the bottom wall 112 and sidewalls 114. The lid assembly 116 can be connected to the sidewalls 114 of the container 110 using removable bolts through appropriately shaped openings, which may have a threaded portion to allow for easy connection of a threaded bolt. The bolts can be removed to allow the lid assembly 116 to be removed from the container 110 so that the solid volume of the semiconductor chemical precursor 150 in the container 110 can be changed or added.

The lid may further comprise one or more external surface features to reciprocate with an external heater. The bottom wall may be configured to reciprocate with an external heater. One or more jacket heaters may be provided around the sidewalls.

A first seal (not shown) is located between an upper surface of the sidewalls 114 and the lower surface of the lid assembly 116 to form a fluid tight seal. In embodiments in which the bottom wall 112 is a separately formed element, a second seal is located between an upper portion of the bottom wall 112 and a lower surface of the sidewalls 114 to form a fluid tight seal. In some embodiment, the bottom wall 112 is integrally formed with the sidewalls 114, eliminating the need for a second seal. In some embodiments where the bottom wall 112 is a separately formed element, the first seal 152 and the second seal are independently an O-ring. In some embodiments (not shown), the lid assembly 116 can be integrally formed with the sidewalls 114 and the bottom wall 112 of the container 110.

Different manifold configurations can be connected to the lid assembly 116 to allow the ampoule 100 to be added to a process chamber. In some embodiments, an inlet line 170 is connected to the inlet port 120. An inlet valve 172 can be positioned on the inlet line 170 between gas source “G” and the inlet port 120. The inlet valve 172 can be integrally formed with the lid assembly 116 or connected to the lid assembly 116 as a separate component. An outlet line 180 can be connected to the outlet port 130. The outlet line 180 of some embodiments includes an outlet valve 182 located between the outlet port 130 and the processing chamber “P”. The inlet valve 172 and outlet valve 182 can be used to isolate the ampoule 100 so that the contents of the cavity 118 are isolated from the environment outside of the container 110. In some embodiments, there are multiple valves along the inlet line 170 as in FIG. 1A and/or the outlet line 180 and/or therebetween as in FIG. 1A. The valves can be manual valves or pneumatic valves.

Carrier gas flow enters the ampoule 100 from the inlet port 120, as discussed with respect to FIG. 3. The carrier gas, indicated by dashed arrow “A” in FIG. 3, enters a first fluid connection 120a and proceeds to at least one flow channel 123 through the ingress opening 121 and contacts the solid volume of the semiconductor chemical precursor at a high velocity after passing through an orifice 162 (not shown), thereby entraining and/or vaporizing the precursor as the carrier gas passes over a surface of the walls of the at least one flow channel 123. Flow then proceeds to a second fluid connection 130b through the outlet passage 131 and exits the ampoule 100 through the outlet port 130, indicated by dashed arrow “B”.

FIG. 4 shows flow paths in an ampoule containing the solid volume of the semiconductor chemical precursor according to an embodiment, as indicated by arrow “C”. Through the ingress opening 121, the carrier gas enters a first section 123a and a second section 123b of the at least one flow channel 123. The carrier gas flows into an outer portion of the first section 123a and an outer portion of the second section 123b of the at least one flow channel 123 and contacts the surface of the walls of the at least one flow channel 123, thus entraining and/or vaporizing the precursor. The carrier gas then proceeds towards an inner portion of the first section 123a and an inner portion of the second section 123b of the at least one flow channel 123, which are respectively in a first section 123a in which the carrier gas flows in a first direction and a second section 123b of the at least one flow channel 123 in which the carrier gas flows in a second direction and exits through the outlet passage 131. In the first section 123a, the carrier gas flows in a clockwise direction, and in the second section 123b, the carrier gas flows in an opposite direction, e.g., in a counterclockwise direction, which is an example of tortuous path.

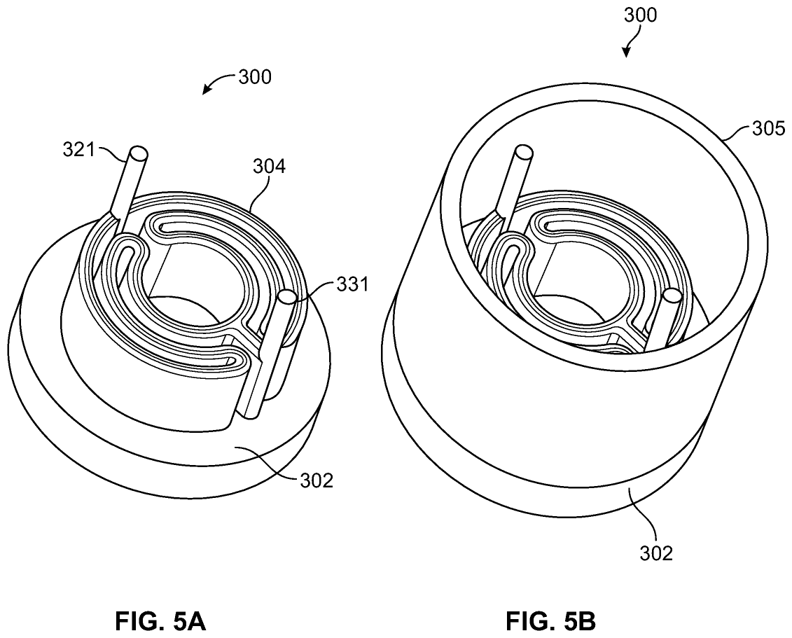

FIG. 5A and FIG. 5B show a mold core 302, a mold shell 304, and a mold/shell assembly 300 for manufacturing of a solid volume of the semiconductor chemical precursor. In reference to FIG. 2, the mold comprises a negative wall 305 that defines the at least one flow channel 123, a first negative profile that defines the first fluid connection 120a, and a second negative profile 331 that defines the second fluid connection 130b. A semiconductor chemical precursor material is poured within the mold/shell assembly 300 to form the solid volume of the semiconductor chemical precursor after curing.

According to one or more embodiments, when the solid volume of the semiconductor chemical precursor contains a minimum quantity of a precursor material, which may depend on the specific precursor material in the composition of the solid volume of the semiconductor chemical precursor and its physical properties, and the chemical composition of the solid volume of the semiconductor chemical precursor, it is expected that the carrier gas will become fully saturated over the flow path distance. As the amount of precursor mass in the ampoule decreases during service, the degree of saturation may decrease. Saturation may change as a function of the width of the at least one flow channel and the composition of the solid volume of the semiconductor chemical precursor. It is understood that as the carrier gas contacts the solid volume of the semiconductor chemical precursor, it entrains the precursor. As a result the mass of the solid volume of the semiconductor chemical precursor may decrease and consequently the at least one flow channel may widen. However, the constant supply of the precursor to maintain a desired level of saturation in the carrier gas is maintained.

Thermocouples, mass flow meters, and pressure gauges may be included in the equipment denoted herein in order to monitor process conditions. In one or more embodiments, a mass flow meter is provided to monitor gas flow into the inlet port. In one or more embodiments, a thermocouple is installed in the lid assembly. In one or more embodiments, a pressure gauge is provided on the inlet line and/or the outlet line. A pressure range within the ampoule in accordance with some embodiments is greater than or equal to 25 torr to less than or equal to 150 torr.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. An ampoule comprising:
a container defining a cavity configured to hold a solid volume of the semiconductor chemical precursor;
an inlet port and an outlet port, both in fluid communication with the solid volume of the semiconductor chemical precursor;
the solid volume of the semiconductor chemical precursor defined by a top edge, a bottom edge, a perimeter and at least one flow channel in the solid volume of the semiconductor chemical precursor; and
at least one flow path defined by the at least one flow channel through which a carrier gas flows in contact with the solid volume of the semiconductor chemical precursor.

2. The ampoule of claim 1, wherein the at least one flow channel defines a labyrinth such that the at least one flow path is tortuous.

3. The ampoule of claim 1, wherein the ampoule further comprises a single inlet and a single outlet.

4. The ampoule of claim 1, wherein the solid volume of the semiconductor chemical precursor comprises a non-porous material.

5. The ampoule of claim 1, wherein the solid volume of the semiconductor chemical precursor comprises a porous material.

6. The ampoule of claim 5, wherein the porous material has a porosity in a range of 5-95 percent by volume.

7. The ampoule of claim 1, wherein a first fluid connection extends from the inlet port to an ingress opening in the solid volume of the semiconductor chemical precursor, the ingress opening in fluid communication with both the first fluid connection and the at least one flow channel; and
a second fluid connection extending from the outlet port to an outlet passage in the solid volume of the semiconductor chemical precursor, the outlet passage in fluid communication with both the second fluid connection and the at least one flow channel.

8. The ampoule of claim 7, wherein the at least one flow channel comprises one or more arcs.

9. The ampoule of claim 8, wherein in the one or more arcs are in fluid communication.

10. The ampoule of claim 9, wherein the one or more arcs are concentric arcs.

11. The ampoule of claim 7, wherein the at least one flow channel comprises a plurality of tortuous passages configured so that flow of the carrier gas through the ingress opening diverts the carrier gas into a first section in a first direction and a second section in a second direction and out the outlet passage.

12. A method forming a film in a semiconductor processing chamber, the method comprising:
flowing a carrier gas through an inlet port of an ampoule having a solid volume of a semiconductor chemical precursor therein;
directing the flow of the carrier gas within the ampoule and in contact with the solid volume of a semiconductor chemical precursor through at least one flow path defined by at least one flow channel in the solid volume of a semiconductor chemical precursor, the at least one flow channel having an ingress opening, through which a carrier gas flows in contact with the solid volume of a semiconductor chemical precursor and an outlet passage through which the carrier gas flows out of the solid volume of a semiconductor chemical precursor; and
flowing the carrier gas and the semiconductor chemical precursor out of the ampoule through the outlet passage to an outlet port.

13. The method of claim 12, further comprising directing the flow of gas through one or more arcs in fluid communication with each other.

14. The method of claim 12, wherein contact of the carrier gas with the solid volume of the semiconductor chemical precursor entrains the precursor into the at least one flow toward the outlet passage.

15. The method of claim 12, wherein the carrier gas flows into first and second sections of the at least one flow channel each flowing in first and second directions through first and second sections of the at least one flow channel, respectively and flowing out the outlet passage.

16. A solid volume of a semiconductor chemical precursor, comprising:
a top edge, a bottom edge, and a perimeter defining a solid volume of the semiconductor chemical precursor, the semiconductor chemical precursor having at least one flow channel, an ingress opening, and an outlet passage, wherein the at least one flow channel is in fluid communication with the ingress opening and the outlet passage; and
at least one flow path defined by the at least one flow channel through which a carrier gas flows in contact with the semiconductor chemical precursor.

17. The solid volume of the semiconductor chemical precursor of claim 16, wherein the semiconductor chemical precursor comprises a non-porous material.

18. The solid volume of the semiconductor chemical precursor of claim 16, wherein the solid volume of the semiconductor chemical precursor comprises a porous material.

19. The solid volume of the semiconductor chemical precursor of claim 16, wherein the solid volume of the semiconductor chemical precursor is manufactured by molding, casting, machining or 3D printing.

20. The solid volume of the semiconductor chemical precursor of claim 19, wherein the molding comprises molding a powder precursor to form the solid volume of the semiconductor chemical precursor.
